(19) United States
(12) Patent Application Publication
(10) Pub. No.: US 2018/0240393 A1
(43) Pub. Date: Aug. 23, 2018

(54) ARRAY SUBSTRATE, METHOD FOR PARTITIONED DRIVING THEREOF, DISPLAY CIRCUIT AND DISPLAY DEVICE

(71) Applicant: BOE TECHNOLOGY GROUP CO., LTD., Beijing (CN)

(72) Inventors: Hui ZHANG, Beijing (CN); Seung-Woo Han, Beijing (KR); Yun-Sik Im, Beijing (KR); Shunhang Zhang, Beijing (CN); Mingfu Han, Beijing (CN)

(21) Appl. No.: 15/712,429

(22) Filed: Sep. 22, 2017

(30) Foreign Application Priority Data
Feb. 23, 2017 (CN) 201710099347.X

(51) Int. Cl. G09G 3/20; H01L 27/12; H01L 29/786

(52) U.S. Cl. CPC G09G 3/2092; H01L 27/124; H01L 29/78648; G09G 2330/028; G09G 2310/0221; G09G 2300/0426; G09G 2300/0408; G09G 2320/0233; G09G 2330/021

(57) ABSTRACT

An array substrate includes a display region including at least two partitions. The array substrate includes a gate driving circuit, first gate electrodes and second gate electrodes. The gate driving circuit is configured to, while inputting a first voltage to the respective first gate electrodes for turning on corresponding thin film transistors according to normal timing, selectively input, to all the second gate electrodes in at least one of the partitions, a second voltage for turning off or turning on all thin film transistors in the partition.

### CROSS-REFERENCE TO RELATED APPLICATION

This application claims priority of Chinese Patent Application No. 201710099347.X filed on Feb. 23, 2017, titled “ARRAY SUBSTRATE, METHOD FOR PARTITIONED DRIVING THEREOF, DISPLAY CIRCUIT AND DISPLAY DEVICE”, contents of which are hereby incorporated by reference in its entirety.

### TECHNICAL FIELD

The present disclosure relates to the technical field of display device processing, and more particularly, to an array substrate, a method for partitioned driving of an array substrate, a display circuit, and a display device.

### BACKGROUND

A thin-film transistor (TFT) is one kind of field effect transistors, which includes a source electrode, a drain electrode and an active area, wherein the source electrode is connected with a data line, the drain electrode is connected with a pixel electrode, a gate electrode is connected with a gate line. The active area is made of a semiconductor material which is generally an amorphous silicon, a polysilicon, a metal oxide semiconductor or the like.

In practical application, in order to reduce power consumption of a display panel, partitioned control may be performed on resolution and a refreshing frequency of the display panel, for example, an region focused by human eyes may be displayed in normal resolution and refreshing frequency, and the remaining regions are displayed with reduced resolution and refreshing frequency. However, the partitioned control easily causes blog mura in the region.

### SUMMARY

There is proposed an array substrate, a method for driving partitions thereof, a display circuit, and a display device.

The present disclosure provides an array substrate, the array substrate including a display region including at least two partitions; the array substrate includes a gate driving circuit, first gate electrodes and second gate electrodes;

the gate driving circuit is configured to, while inputting a first voltage to the respective first gate electrodes for turning on corresponding thin film transistors according to normal timing, selectively input, to all the second gate electrodes in at least one of the partitions, a second voltage for turning off or turning on all thin film transistors in the partition.

In an embodiment, the gate driving circuit includes a first gate line and a second gate line, wherein,

the first gate electrode is connected with the first gate line;

a number of the second gate line corresponds to a number of the partitions, and the respective second gate lines are respectively connected with all the second gate electrodes in the corresponding partition.

In an embodiment, the gate driving circuit further includes a first driving circuit and a second driving circuit, wherein,

the first driving circuit is disposed on both sides or one side of a display panel of the array substrate, and is configured to input the first voltage to the respective first gate electrodes according to the normal timing;

the second driving circuit is integrated in an external integrated circuit, and is configured to selectively input the second voltage to all the second gate electrodes in at least one of the partitions.

In an embodiment, the array substrate further includes a glass substrate, a gate insulation layer, an active layer, a source and drain electrode layer, and a protection layer;

the glass substrate, the first gate electrode, the gate insulation layer, the active layer, the source and drain electrode layer, the protection layer and the second gate electrode are disposed in this order from bottom to above;

or,

the glass substrate, the second gate electrode, the gate insulation layer, the active layer, the source and drain electrode layer, the protection layer and the first gate electrode are disposed in this order from bottom to above.

In an embodiment, the first gate electrode and the second gate electrode are fabricated by a transparent conductive material.

In an embodiment, the display region of the array substrate includes nine partitions, and the nine partitions are distributed in an array with three lines multiplied by three columns.

As another technical solution, the present disclosure further provides a display circuit including an array substrate, wherein the array substrate is the above-mentioned array substrate provided by the present disclosure.

As another technical solution, the present disclosure further provides a display device including a display circuit, wherein the display circuit is the above-described display circuit provided by the present disclosure.

As another technical solution, the present disclosure further provides a method for driving partitions of an array substrate, wherein a display region of the array substrate includes at least two partitions, and the array substrate includes second gate electrodes and first gate electrodes; the method for driving the partitions of the array substrate includes:

while inputting a first voltage to the respective first gate electrodes for turning on corresponding thin film transistors according to normal timing, selectively inputting, to all the second gate electrodes in at least one of the partitions, a second voltage for turning off or turning on all thin film transistors in the partition.

### BRIEF DESCRIPTION OF THE DRAWINGS

FIG. 1 is a schematic diagram of partitions of a conventional array substrate.

FIG. 2 is a schematic diagram of partitions of an array substrate provided by an embodiment of the present disclosure.

FIG. 3 is a structural diagram of an array substrate provided by an embodiment of the present disclosure.

### DETAILED DESCRIPTION

In order that those skilled in the art will better understand the technical solutions of the present disclosure, an array substrate, a method for driving partitions thereof, a display circuit, and a display device provided by the present disclosure will be described below in detail with reference to the accompanying drawing.

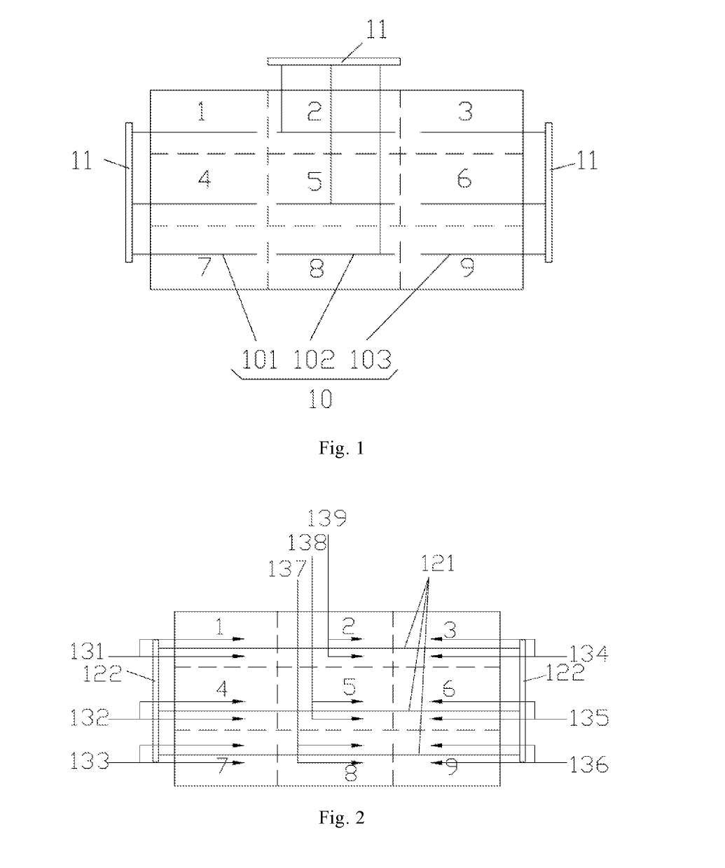

FIG. 1 is a schematic diagram of partitions of a conventional array substrate. A display region of the array substrate is divided into 3×3 partitions, i.e., a first partition 1 to a ninth partition 9. Correspondingly, a gate line on the same line is broken into three segments according to the partitions, for example, a gate line 10 is divided into three segments (101, 102, 103), and such segments are independently controlled by using three sets of gate driver on array (GOA) circuits 11.

However the above-described array substrate is additionally provided with one set of GOA circuit 11, and it is also required to add cross-line connection between the fifth partition 5 and an output end of the GOA, this not only increases process difficulty and complexity in panel design, causes cost increase, but also easily produces delay difference between the gate lines of the respective partitions, thereby resulting in blog mura in the region.

In order to solve the problem, the present disclosure proposes an array substrate, a method for driving partitions thereof, a display circuit and a display device as follows.

The array substrate provided by the present disclosure has a display region which includes at least two partitions. The array substrate includes a gate driving circuit, second gate electrodes and first gate electrodes. The gate driving circuit, while inputting a first voltage that can turn on a thin film transistor to the respective first gate electrodes based on normal timing, selectively inputs, to all the second gate electrodes in at least one of the partitions, a second voltage that can turn off or turn on all thin film transistors in the partition. The normal timing refers to a control timing that controls the thin film transistors on each line or each column to be turned on in turn.

When the above-described first voltage is input to the gate electrode, an active region becomes active, a source electrode and a drain electrode are electrically connected, at this time, the thin film transistor is turned on, and a data line signal could be transferred to a pixel electrode. On the contrary, when the above-mentioned second voltage is input to the gate electrode, the active region becomes inactive, and the source electrode is electrically disconnected from the drain electrode, at this time, the thin film transistor is turned off, and the data line signal is blocked. In actual application, for an n-type thin film transistor, the above-described first voltage is a first voltage, and the above-described second voltage is a second voltage or the voltage is zero.

Based on the principle, the array substrate provided by the present disclosure is provided with dual-gate electrodes, i.e., the first gate electrode and the second gate electrode. The gate driving circuit inputs the first voltage to the respective first gate electrodes based on the normal timing. Meanwhile, the gate driving circuit selectively inputs the second voltage to all the second gate electrodes in the at least one partition. The data line signals in the partition of the second gate electrodes, to which the second voltage is input, are blocked, but the data line signals in the remaining partition are refreshed based on the normal timing, in this way, partitioned control on resolution and a refreshing frequency of a display panel is realized. Because there is no need to provide any GOA circuit or cross-line connection, the way of realizing partition driving of the panel becomes simpler, and the gate lines are not required to be segmented. In this way, the situation in which delay difference occurs among the gate lines in the respective partitions could be improved, and then the risk of producing blog mura in the region is reduced.

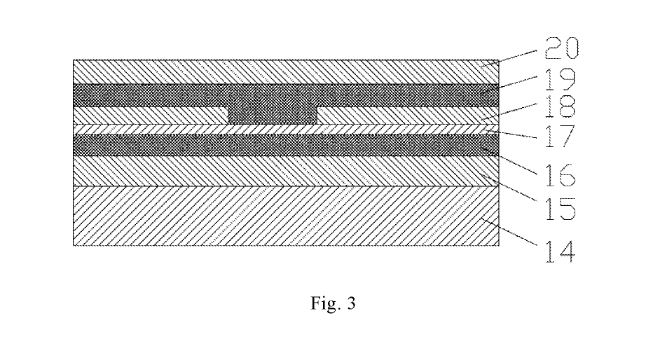

Specific embodiments of the array substrate provided by the present disclosure will be described below in detail. In particular, FIG. 2 is a schematic diagram of partitions of an array substrate provided by an embodiment of the present disclosure. FIG. 3 is a structural diagram of an array substrate provided by an embodiment of the present disclosure. Referring to FIGS. 2 and 3, in the present embodiment, the array substrate includes a glass substrate 14, a first gate electrode 15, a gate insulation layer 16, an active layer 17, a source electrode layer 18, a protection layer 19 and a second gate electrode 20 in this order from bottom to top. The first gate electrode 15 and the second gate electrode 20 could be fabricated by a transparent conductive material.

When a gate driving circuit inputs a first voltage to the respective first gate electrodes 15, a thin film transistor is turned on, at this time, if the gate driving circuit inputs a second voltage to the second gate electrode 20 connected with the thin film transistor, a cutoff voltage of the thin film transistor may forwardly drift to above 10V, such that the thin film transistor is turned off. Therefore, all of the thin film transistors in the partition of the second gate electrodes 20, to which the second voltage is input, are turned off, the gate line signals are blocked, but the data line signals in the remaining partition are refreshed according to the normal timing. In this way, partitioned control on resolution and a refreshing frequency of a display panel is realized. Certainly, in practical application, positions of the first gate electrode 15 and the second gate electrode 20 are replaceable, that is, the glass substrate 14, the second gate electrode 20, the gate insulation layer 16, the active layer 17, the source electrode layer 18, the protection layer 19 and the first gate electrode 15 are provided in this order from bottom to top.

In the present embodiment, as shown in FIG. 2, a display region of the array substrate is divided into 9 partitions, and the 9 partitions are distributed in a rectangular array with 3 lines multiplied by 3 columns, i.e., the first partition 1 to the ninth partition 9. Furthermore, the gate driving circuit further includes second gate lines, first gate lines 121, first driving circuits 122 and a second driving circuit (not shown in the figure), wherein the first gate electrode is connected with the first gate line 121. The number of the second gate lines corresponds to the number of the partitions, i.e., 9, and the respective second gate lines (131˜139) are connected to all the second gate electrodes in the respective partitions (the first partition 1 to the ninth partition 9) in a one-to-one corresponding manner. The first driving circuits 122 are disposed on both sides or one side of the display panel of the array substrate, and are configured to input the first voltage to the respective first gate electrodes according to the normal timing. The second driving circuit is integrated in an external integrated circuit (IC circuit), and is configured to selectively input the second voltage to all the second gate electrodes in the at least one partition, to turn off or turn on all the thin film transistors in the partition. In practical application, the number and the manner of the partitions can be set according to the specific situation, and the present disclosure does not impose any limitation on this.

From the above we can know, as compared to the related art, in the array substrate provided by the embodiment of the present disclosure, there is no need to provide any GOA circuit or cross-line connection, the way of realizing partition driving of the panel becomes simpler, and the gate lines are not required to be segmented. In this way, the situation in which delay difference occurs among the gate lines in the respective partitions could be improved, and then the risk of producing blog mura in the region is reduced.

As another technical solution, an embodiment of the present disclosure further provides a display circuit including an array substrate, wherein the array substrate is the above-mentioned array substrate provided by the embodiment of the present disclosure.

The display circuit provided by the embodiment of the present disclosure employs the above-described array substrate provided by the embodiment of the present disclosure, in this way, not only the way of realizing partition driving of the panel becomes simpler, but also the situation in which delay difference occurs among the gate lines in the respective partitions could be improved, and the risk of producing blog mura in the region is reduced.

As another technical solution, an embodiment of the present disclosure further provides a display device including a display circuit, wherein the array substrate uses the above-described display circuit provided by the embodiment of the present disclosure.

The display device provided by the embodiment of the present disclosure employs the above-described display circuit provided by the embodiment of the present disclosure, in this way, not only the way of realizing partition driving of the panel becomes simpler, but also the situation in which delay difference occurs among the gate lines in the respective partitions could be improved, and the risk of producing blog mura in the region is reduced.

As another technical solution, an embodiment of the present disclosure further provides a method for driving partitions of an array substrate, a display region of the array substrate includes at least two partitions. The array substrate includes second gate electrodes and first gate electrodes, the specific structure of the array substrate is as shown in FIG. 3, since detailed description have been made in the above-described embodiment, repetitions are omitted herein.

The method for driving the partitions of the array substrate includes the following steps.

While inputting a first voltage that can turn on a thin film transistor to respective first gate electrodes according to normal timing, selectively inputting, to all second gate electrodes in at least one of the partitions, a second voltage that can turn off or turn on all thin film transistors in the partition.

In the method for driving the partitions of the array substrate provided by the embodiment of the present disclosure, partitioned control on resolution and a refreshing frequency of a display panel is realized, meanwhile, there is no need to provide any GOA circuit or cross-line connection, in this way, the way of realizing partition driving of the panel becomes simpler, and the gate lines are not required to be segmented, thus, the situation in which delay difference occurs among the gate lines in the respective partitions could be improved, and then the risk of producing blog mura in the region is reduced.

It is to be understood that the above embodiments are merely exemplary embodiments employed for the purpose of illustrating the principles of the present disclosure, but the present disclosure is not limited thereto. It will be apparent to those skilled in the art that various changes and modifications can be made therein without departing from the spirit and essence of the present disclosure, and such changes and modifications are also regarded to be within the scope of the present disclosure.

What is claimed is:

1. An array substrate, comprising a display region comprising at least two partitions;
wherein the array substrate comprises a gate driving circuit, first gate electrodes and second gate electrodes;
the gate driving circuit is configured to, while inputting a first voltage to the respective first gate electrodes for turning on corresponding thin film transistors according to normal timing, selectively input, to all the second gate electrodes in at least one of the partitions, a second voltage for turning off or turning on all thin film transistors in the partition.

2. The array substrate of claim 1, wherein the gate driving circuit comprises a first gate line and a second gate line, wherein,
the first gate electrode is connected with the first gate line;
a number of the second gate line corresponds to a number of the partitions, and the respective second gate lines are respectively connected with all the second gate electrodes in the corresponding partition.

3. The array substrate of claim 1, wherein the gate driving circuit further comprises a first driving circuit and a second driving circuit, wherein,
the first driving circuit is disposed on both sides or one side of a display panel of the array substrate, and is configured to input the first voltage to the respective first gate electrodes according to the normal timing; and
the second driving circuit is integrated in an external integrated circuit, and is configured to selectively input the second voltage to all the second gate electrodes in at least one of the partitions.

4. The array substrate of claim 2, wherein the gate driving circuit further comprises a first driving circuit and a second driving circuit, wherein,
the first driving circuit is disposed on both sides or one side of the display panel of the array substrate, and is configured to input the first voltage to the respective first gate electrodes according to the normal timing; and
the second driving circuit is integrated in an external integrated circuit, and is configured to selectively input the second voltage to all the second gate electrodes in at least one of the partitions.

5. The array substrate of claim 1 further comprising a glass substrate, a gate insulation layer, an active layer, a source and drain electrode layer, and a protection layer; and
the glass substrate, the first gate electrode, the gate insulation layer, the active layer, the source and drain electrode layer, the protection layer and the second gate electrode are disposed in this order from bottom to above.

6. The array substrate of claim 1 further comprising a glass substrate, a gate insulation layer, an active layer, a source and drain electrode layer, and a protection layer; and
the glass substrate, the second gate electrode, the gate insulation layer, the active layer, the source and drain electrode layer, the protection layer and the first gate electrode are disposed in this order from bottom to above.

7. The array substrate of claim 2 further comprising a glass substrate, a gate insulation layer, an active layer, a source and drain electrode layer and a protection layer; and
the glass substrate, the first gate electrode, the gate insulation layer, the active layer, the source and drain electrode layer, the protection layer and the second gate electrode are disposed in this order from bottom to above.

8. The array substrate of claim 2 further comprising a glass substrate, a gate insulation layer, an active layer, a source and drain electrode layer and a protection layer; and
the glass substrate, the second gate electrode, the gate insulation layer, the active layer, the source and drain electrode layer, the protection layer and the first gate electrode are disposed in this order from bottom to above.

9. The array substrate of claim 5, wherein the first gate electrode and the second gate electrode are fabricated by a transparent conductive material.

10. The array substrate of claim 1, wherein the display region of the array substrate comprises nine partitions, and the nine partitions are distributed in an array with three lines multiplied by three columns.

11. The array substrate of claim 1, wherein the display region of the array substrate comprises nine partitions, and the nine partitions are distributed in an array with three lines multiplied by three columns.

12. A display circuit comprising an array substrate, wherein the array substrate is the array substrate of claim 1.

13. A display circuit comprising an array substrate, wherein the array substrate is the array substrate of claim 2.

14. A display circuit comprising an array substrate, wherein the array substrate is the array substrate of claim 3.

15. A display circuit comprising an array substrate, wherein the array substrate is the array substrate of claim 4.

16. A display circuit comprising an array substrate, wherein the array substrate is the array substrate of claim 12.

17. A display device comprising a display circuit, wherein the display circuit is the display circuit of claim 13.

18. A display device comprising a display circuit, wherein the display circuit is the display circuit of claim 14.

19. A display device comprising a display circuit, wherein the display circuit is the display circuit of claim 15.

20. A method for partitioned driving of an array substrate, a display region of the array substrate comprising at least two partitions, wherein the array substrate comprises second gate electrodes and first gate electrodes;
the method for partitioned driving comprising:
while inputting a first voltage to the respective first gate electrodes for turning on corresponding thin film transistors according to normal timing, selectively inputting, to all the second gate electrodes in at least one of the partitions, a second voltage for turning off or turning on all thin film transistors in the partition.
